(19) United States
(12) Patent Application Publication
(10) Pub. No.: US 2010/0295111 A1
(43) Pub. Date: Nov. 25, 2010

(54) SEMICONDUCTOR DEVICE AND METHOD FOR FABRICATING THE SAME

(76) Inventor: Koichi KAWASHIMA, Hyogo (JP)

Correspondence Address: MCDERMOTT WILL & EMERY LLP, 600 13TH STREET, NW, WASHINGTON, DC, 20005-3096, US

(21) Appl. No.: 12/718,725

(22) Filed: Mar. 5, 2010

(30) Foreign Application Priority Data
May 20, 2009 (JP) 2009-122466

(51) Int. Cl. H01L 27/115; H01L 21/8246

(52) U.S. Cl. 257/314; 438/586; 257/355; 438/237; 257/E21.662; 257/E27.103; 257/324

(57) ABSTRACT

A semiconductor device includes a semiconductor element and a protection diode formed on a semiconductor substrate. Over the semiconductor substrate, a first interlayer dielectric layer is formed so as to cover the semiconductor element and the protection diode. In the first interlayer dielectric layer, a first plug electrically connected to the semiconductor element and a second plug electrically connected to the protection diode are formed. The area of the top surface of the second plug is greater than the area of the top surface of the first plug.

### CROSS-REFERENCE TO RELATED APPLICATION

This application claims priority to Japanese Patent Application No. 2009-122466 filed on May 20, 2009, the disclosure of which including the specification, the drawings, and the claims is hereby incorporated by reference in its entirety.

### BACKGROUND

The present disclosure relates to semiconductor devices and methods for fabricating the same, and more particularly to semiconductor devices having multilevel interconnect structures, a typical example of which is a non-volatile semiconductor memory which stores electrical charge in a trapping layer, and to a method for fabricating the same.

In recent years, various forms of non-volatile semiconductor memories have been proposed. For example, attention has been given to a non-volatile semiconductor memory which has bit lines made of diffusion layers and word lines made of conductive layers of polysilicon, etc., being disposed so as to intersect each other, and which stores charge in a trapping layer, because a high degree of integration can be easily achieved in such a non-volatile semiconductor memory (see, e.g., the specification of U.S. Patent Application Publication No. 2006/0214218: Patent Document 1).

However, a non-volatile semiconductor memory has a characteristic such that charge is trapped in a charge-trapping layer by various charging phenomena which occur during a fabrication process, thereby causing a change in the threshold voltage. Therefore, a need exists for a technology to prevent the charge generated during a fabrication process from reaching the semiconductor memory.

Among these charging phenomena, one charging phenomenon is reported which is caused during formation of a metal interconnect connecting a semiconductor memory and a power supply, by charge accumulated in the metal interconnect; and a technology to prevent the charge due to this charging phenomenon from reaching the semiconductor memory by means of a protection diode is proposed (see, e.g., Japanese Unexamined Patent Application Publication No. H10-173157: Patent Document 2).

According to Patent Document 2, after connection has been made between a gate electrode of a memory cell and a protection diode using a metal interconnect in a first layer, a contact opening to connect a metal interconnect in a second layer is formed by dry etching. Therefore, charge generated by dry etching can be dissipated to the substrate by means of the protection diode, thereby preventing breakdown of a gate dielectric layer.

### SUMMARY

However, the technology as previously mentioned in the Background section is intended to prevent breakdown of a gate dielectric layer of a semiconductor memory, and assumes that stress is applied at a high voltage. Meanwhile, in a non-volatile semiconductor memory which stores charge in a trapping layer, even a small amount of accumulated charge insufficient to cause breakdown has an effect on its characteristics. Thus, there is a greater need for protection against charge accumulation than in a case of a non-volatile semiconductor memory having a floating-gate electrode. As such, in a non-volatile semiconductor memory which stores charge in a trapping layer, a technology is required to further reduce the amount of charge accumulated in a metal interconnect when a contact opening to a metal interconnect is formed.

In addition, the present inventor has realized that, in an actual dry etching process, a charging phenomenon which has not been assumed to exist in the prior art occurs, and charge is accumulated in the trapping layer. Moreover, a gate electrode may be either negatively or positively charged. Thus, in a configuration where a protection diode functions only under a condition where a gate electrode is negatively charged as in the prior art, a problem exists in that charge accumulation in the trapping layer cannot be avoided if there is a condition where the gate electrode is positively charged.

The present disclosure achieves a semiconductor device which prevents accumulation of a small amount of charge insufficient to cause breakdown.

The present disclosure assumes that a semiconductor device has a configuration in which the area of the top surface of a plug connected to a protection diode is greater than the area of the top surface of a plug connected to a semiconductor element.

More specifically, a first semiconductor device includes a semiconductor element and a protection diode both formed on a semiconductor substrate, a first interlayer dielectric layer formed over the semiconductor substrate so as to cover the semiconductor element and the protection diode, a first plug formed in the first interlayer dielectric layer and electrically connected to the semiconductor element, and a second plug formed in the first interlayer dielectric layer and electrically connected to the protection diode; and the area of the top surface of the second plug is greater than the area of the top surface of the first plug.

According to the first semiconductor device, when a first contact opening and a second contact opening are formed in the first interlayer dielectric layer to form the first plug and the second plug, the second contact opening reaches the protection diode before the first contact opening reaches a gate electrode of the semiconductor element. Therefore, the charge generated during dry etching to form the first and the second contact openings is less likely to be accumulated in a capacitor formed between the first contact opening and the gate electrode. Thus, an effect to dissipate the charge to the substrate is enhanced, thereby preventing accumulation of a small amount of charge insufficient to cause breakdown.

A second semiconductor device includes a semiconductor element and a protection diode both formed on a semiconductor substrate, a first interlayer dielectric layer formed over the semiconductor substrate so as to cover the semiconductor element and the protection diode, a first plug formed in the first interlayer dielectric layer and electrically connected to the semiconductor element, a second plug formed in the first interlayer dielectric layer and electrically connected to the protection diode, a first interconnect electrically connected to the first plug, and a second interconnect electrically connected to the second plug, both formed on the first interlayer dielectric layer, a second interlayer dielectric layer formed over the first interlayer dielectric layer so as to cover the first interconnect and the second interconnect, a third plug formed in the second interlayer dielectric layer and electrically connected to the first interconnect, and a fourth plug formed in the second interlayer dielectric layer and electrically connected to the second interconnect; and the area of the top surface of the fourth plug is greater than the area of the top surface of the third plug.

According to the second semiconductor device, when a third and a fourth contact openings are formed in the second interlayer dielectric layer to form the third and the fourth plugs, the fourth contact opening reaches the second interconnect before the third contact opening reaches the first interconnect. Therefore, an effect to dissipate the charge, generated during dry etching to form the third and the fourth contact openings, to the substrate can be enhanced, thereby preventing accumulation of a small amount of charge insufficient to cause breakdown.

A method for fabricating a first semiconductor device includes the acts of (a) forming a semiconductor element on a semiconductor substrate, (b) forming a protection diode on the semiconductor substrate, (c) forming a first interlayer dielectric layer over the semiconductor substrate so as to cover the semiconductor element and the protection diode, (d) forming a first contact opening reaching the semiconductor element, and a second contact opening reaching the protection diode both in the first interlayer dielectric layer, and (e) filling the first contact opening and the second contact opening with a conductive material; and in the act (d), the second contact opening reaches the protection diode before the first contact opening reaches the semiconductor element.

According to the method for fabricating the first semiconductor device, the second contact opening reaches the protection diode before the first contact opening reaches the semiconductor element. Therefore, the charge, generated by dry etching when the first and the second contact openings are formed in the first interlayer dielectric layer, is less likely to be accumulated in a capacitor formed between the first contact opening and the semiconductor element. Thus, an effect to dissipate the charge to the substrate is enhanced, thereby preventing accumulation of a small amount of charge insufficient to cause breakdown, while the semiconductor device is fabricated.

A method for fabricating a second semiconductor device includes the acts of (a) forming a semiconductor element on a semiconductor substrate, (b) forming a protection diode on the semiconductor substrate, (c) forming a first interlayer dielectric layer over the semiconductor substrate so as to cover the semiconductor element and the protection diode, (d) forming a first contact opening reaching the semiconductor element, and a second contact opening reaching the protection diode both in the first interlayer dielectric layer, (e) filling the first contact opening and the second contact opening with a conductive material, and forming a first plug and a second plug, respectively, (f) forming a first interconnect so as to be electrically connected to the first plug, and forming a second interconnect so as to be electrically connected to the second plug, both on the first interlayer dielectric layer, (g) forming a second interlayer dielectric layer over the first interlayer dielectric layer so as to cover the first and the second interconnects, (h) forming a third contact opening reaching the first interconnect and a fourth contact opening reaching the second interconnect both in the second interlayer dielectric layer, and (i) filling the third contact opening and the fourth contact opening with a conductive material, and forming a third plug and a fourth plug, respectively; and in the act (h), the fourth contact opening reaches the second interconnect before the third contact opening reaches the first interconnect.

According to the method for fabricating the second semiconductor device, the fourth contact opening reaches the second interconnect before the third contact opening reaches the first interconnect. Therefore, an effect to dissipate the charge, generated during dry etching to form the third and the fourth contact openings, to the substrate can be enhanced, thereby preventing accumulation of a small amount of charge insufficient to cause breakdown, while the semiconductor device is fabricated.

### BRIEF DESCRIPTION OF THE DRAWINGS

FIGS. 1A and 1B are diagrams to illustrate a charge accumulation mechanism in a semiconductor device. FIG. 1A is a cross-sectional view, and FIG. 1B is an equivalent circuit diagram.

FIG. 2 is an equivalent circuit diagram reflecting an actual condition of the circuit during the fabrication process of the semiconductor device shown in FIGS. 1A and 1B.

FIGS. 3A and 3B are diagrams illustrating a semiconductor device in accordance with the first embodiment. FIG. 3A is a cross-sectional view, and FIG. 3B is an equivalent circuit diagram.

FIGS. 4-11 are cross-sectional views illustrating the fabrication steps of a semiconductor device in accordance with the first embodiment.

FIG. 12 is an equivalent circuit diagram reflecting an actual condition of the circuit during the fabrication process of a semiconductor device in accordance with the first embodiment.

FIG. 13 is a cross-sectional view illustrating a variation of a semiconductor device in accordance with the first embodiment.

FIGS. 14-17 are cross-sectional views illustrating a variation of the fabrication steps of a semiconductor device in accordance with the first embodiment.

FIG. 18 is a cross-sectional view illustrating another variation of a semiconductor device in accordance with the first embodiment.

FIG. 19 is a cross-sectional view illustrating yet another variation of a semiconductor device in accordance with the first embodiment.

FIG. 20 is a top view illustrating a semiconductor device in accordance with the first embodiment.

FIGS. 21A-21E are top views illustrating possible shape variations of contact openings of a semiconductor device in accordance with the first embodiment.

FIG. 22 is a top view illustrating a variation of a semiconductor device in accordance with the first embodiment.

FIGS. 23A and 23B are diagrams illustrating a semiconductor device in accordance with the second embodiment. FIG. 23A is a cross-sectional view, and FIG. 23B is an equivalent circuit diagram.

FIGS. 24-28 are cross-sectional views illustrating the fabrication steps of a semiconductor device in accordance with the second embodiment.

FIG. 29 is an equivalent circuit diagram reflecting an actual condition of the circuit during the fabrication process of a semiconductor device in accordance with the second embodiment.

FIG. 30 is a cross-sectional view illustrating a variation of a semiconductor device in accordance with the second embodiment.

FIG. 31 is an equivalent circuit diagram reflecting an actual condition of the circuit during the fabrication process of a variation of a semiconductor device in accordance with the second embodiment.

FIG. 32 is a top view illustrating an example of a semiconductor device in accordance with the second embodiment.

FIG. 33 is a top view illustrating another example of a semiconductor device in accordance with the second embodiment.

FIG. 34 is a top view illustrating a variation of a semiconductor device in accordance with the second embodiment.

FIG. 35 is a top view illustrating another variation of a semiconductor device in accordance with the second embodiment.

### DETAILED DESCRIPTION

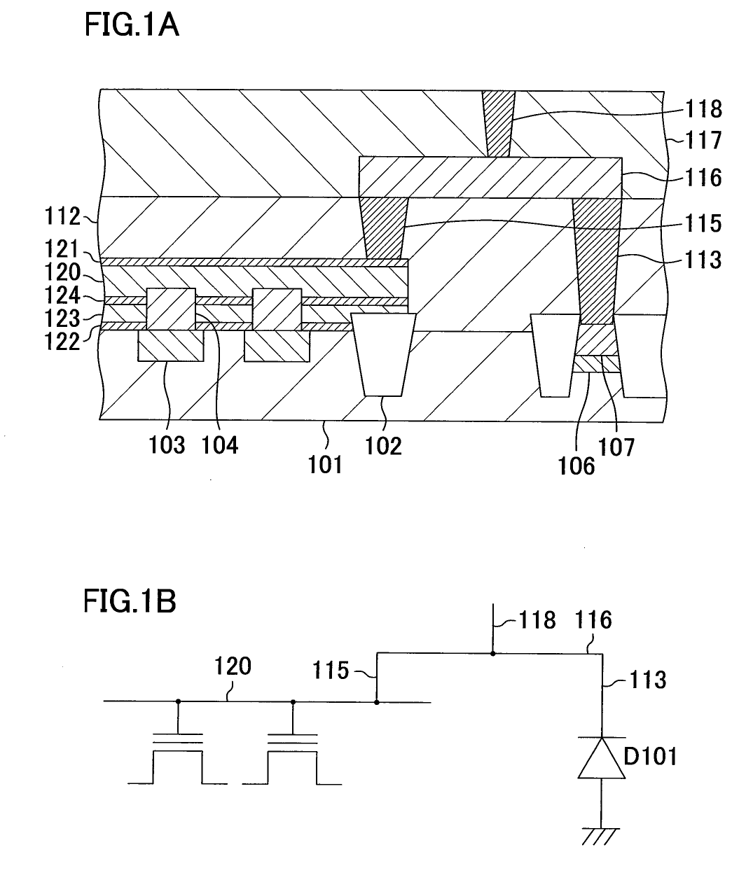

A previously unrecognized charging phenomenon which the present inventor has found will first be described. In a semiconductor device having a configuration as shown in FIGS. 1A and 1B, the following phenomenon occurs.

First, a configuration of an example semiconductor device will be described. As shown in FIG. 1A, in upper portions of a semiconductor substrate 101 made of silicon, etc., a plurality of element isolation regions 102 each made of a buried oxide layer are formed. Also, in upper portions of the semiconductor substrate 101, a plurality of source/drain regions 103 each made of an n-type impurity diffusion layer are formed spaced apart from each other; and over each of the source/drain regions 103, a bit-line buried oxide layer 104 is formed. Also, over each of active regions between the source/drain regions 103, a floating electrode 123 which stores accumulated charge is formed over a dielectric layer 122. Over each floating electrode 123, a gate electrode 120, which functions as a word line, and is made of polycrystalline silicon doped with an n-type impurity such as phosphorus, is formed over an inter-electrode dielectric layer 124, so as to intersect the bit-line buried oxide layers 104.

In addition, formed in upper portions of the semiconductor substrate 101 are a pn junction region formed of a p-type impurity diffusion layer 106 and an n-type impurity diffusion layer 107. A metal silicide layer 121 is formed over the gate electrode 120. An interlayer dielectric layer 112 is formed over the gate electrode 120, the bit-line buried oxide layers 104, and the element isolation regions 102. In the interlayer dielectric layer 112, a contact plug 115 connected to the gate electrode 120, and a contact plug 113 connected to the pn junction region, are formed. A metal interconnect 116 is formed which connects the contact plug 115, connected to the gate electrode 120, and the contact plug 113, connected to the pn junction region; and an interlayer dielectric layer 117 which covers the metal interconnect 116 is formed. Furthermore, a contact plug 118, which connects the metal interconnect 116 and a metal interconnect in an upper layer (not shown), is formed in the interlayer dielectric layer 117.

The semiconductor device shown in FIG. 1A can be represented by an equivalent circuit as shown in FIG. 1B. The pn junction region formed of a p-type impurity diffusion layer 106 and an n-type impurity diffusion layer 107, collectively form a junction diode D101. A negative charging current, caused by a fluctuation of plasma, etc., which is generated while a contact opening is formed to form the contact plug 118 in the interlayer dielectric layer 117, can be dissipated to a ground potential through the junction diode D101. Accordingly, a high voltage caused by a fluctuation of plasma, etc., is no longer applied to the gate electrode 120 of the semiconductor element, thereby preventing breakdown of the gate dielectric layer 122 formed between the floating electrodes 123 and the substrate 101.

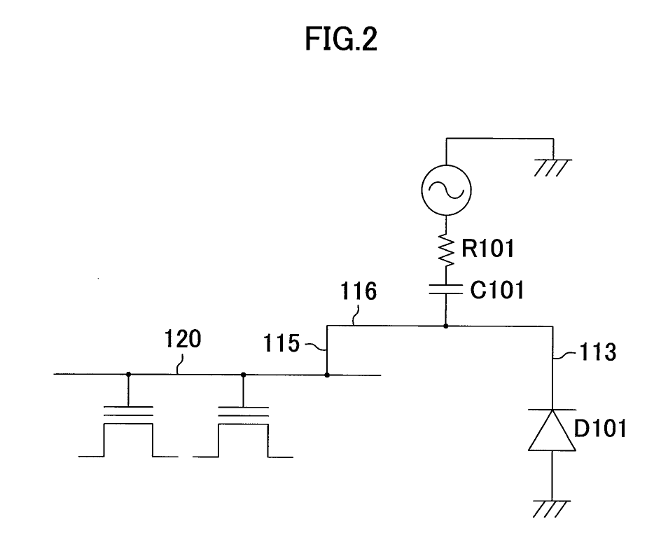

However, the present inventor has recognized that the amount of charge which is actually accumulated during dry etching to form the contact plug 118 connecting the metal interconnect 116 and the metal interconnect in an upper layer, has not been taken into account in the equivalent circuit shown in FIG. 1B. The present inventor has found that, in order to determine the amount of charge which is actually accumulated during dry etching, the equivalent circuit shown in FIG. 2 needs to be used instead.

As shown in FIG. 2, when a contact opening is formed by dry etching to form the contact plug 118, a plasma source used for dry etching acts as an alternating current (AC) power supply, and a remaining layer of the interlayer dielectric layer 117 acts as a capacitor C101. Also, the contact opening acts as a resistor R101. According to this equivalent circuit diagram, while dry etching is performed, the capacitor C101 experiences a change in the capacitance depending on the material and the remaining layer thickness of the interlayer dielectric layer 117, thus charge continues to accumulate. As such, a part of the charge accumulated in the capacitor C101 is not dissipated to the substrate through the junction diode D101, but is trapped in the gate dielectric layer 122 as a trapping layer, thereby causing a change in the threshold voltage.

Also in a case where the metal interconnect 116 of the semiconductor device of FIG. 1A is a buried interconnect, a remaining layer formed during trench formation acts as a capacitor while a interconnect trench is formed, thereby causing a same phenomenon to occur, and charge is accumulated.

Example embodiments will now be described below in terms of a semiconductor device which is designed to avoid the charging phenomenon which the present inventor has found to occur in conventional semiconductor devices.

### First Embodiment

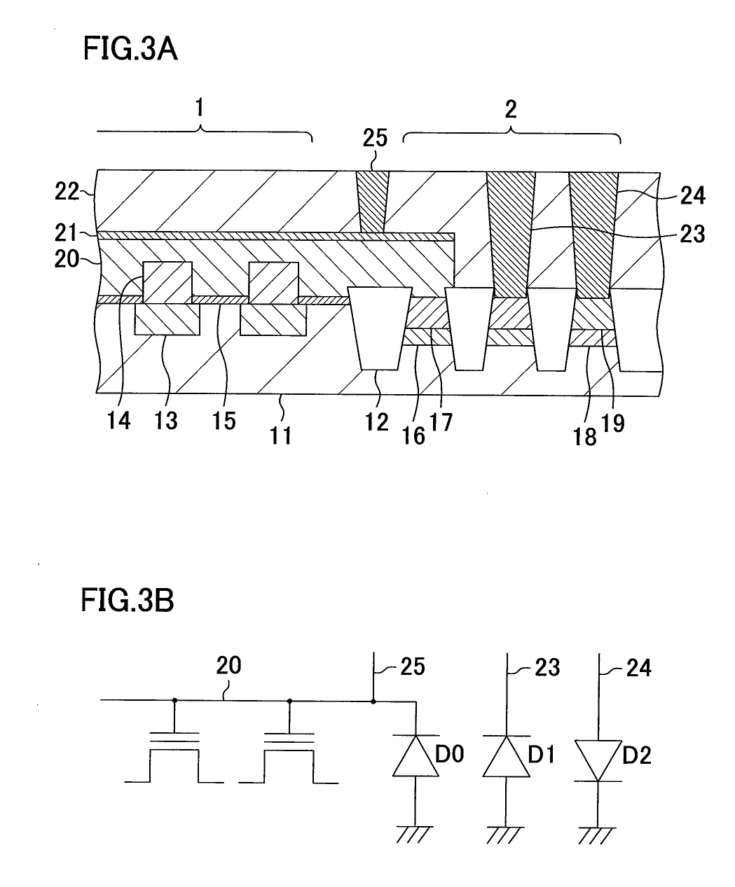

FIGS. 3A and 3B illustrate a semiconductor device according to the first embodiment. FIG. 3A shows a cross-sectional configuration thereof, and FIG. 3B shows a circuit configuration thereof. The semiconductor device according to this embodiment is a semiconductor memory device, and includes a semiconductor element 1 to be protected and a protection diode 2.

The semiconductor device of this embodiment may include multiple ones of the semiconductor element 1, but the following description will be provided in terms of that including a single semiconductor element 1.

As shown in FIG. 3A, in upper portions of a semiconductor substrate 11 made of silicon, etc., element isolation regions 12 each made of a buried oxide layer are formed. In upper portions of the semiconductor substrate 11, a plurality of source/drain regions 13 each made of an n-type impurity diffusion layer are formed spaced apart from each other; and over each of the source/drain regions 13, a bit-line buried oxide layer 14 is formed. Over each of active regions between the source/drain regions 13 is formed a trapping layer 15 which has a charge-trapping site, and which is made of, for example, a multilayer film formed of silicon oxide (SiO₂), silicon nitride (SiN), and silicon oxide (SiO₂) (so called “ONO layer”). Over each trapping layer 15, a gate electrode 20 which functions as a word line, and is made of polycrystalline silicon doped with an n-type impurity such as phosphorus, is formed so as to intersect the bit-line buried oxide layers 14. The semiconductor element 1, which is a semiconductor memory, is formed from these components.

In addition, in upper portions of the semiconductor substrate 11 are formed a plurality of pn junction regions each formed of a p-type impurity diffusion layer 16 and an n-type impurity diffusion layer 17, and an np junction region formed of an n-type impurity diffusion layer 18 and a p-type impurity diffusion layer 19, which collectively form the protection diode 2. The gate electrode 20 is connected to one of the pn junction regions. Over the gate electrode 20, a metal silicide layer 21 is formed. An interlayer dielectric layer 22 is formed so as to cover the gate electrode 20, the bit-line buried oxide layers 14, and element isolation regions 12. In the interlayer dielectric layer 22 are formed a contact plug 25 connected to the gate electrode 20, a contact plug 23 connected to one of the pn junction regions, and a contact plug 24 connected to the np junction region. The area of each top surface of the contact plug 23 and the contact plug 24 is greater than the area of the top surface of the contact plug 25, which is connected to the gate electrode 20.

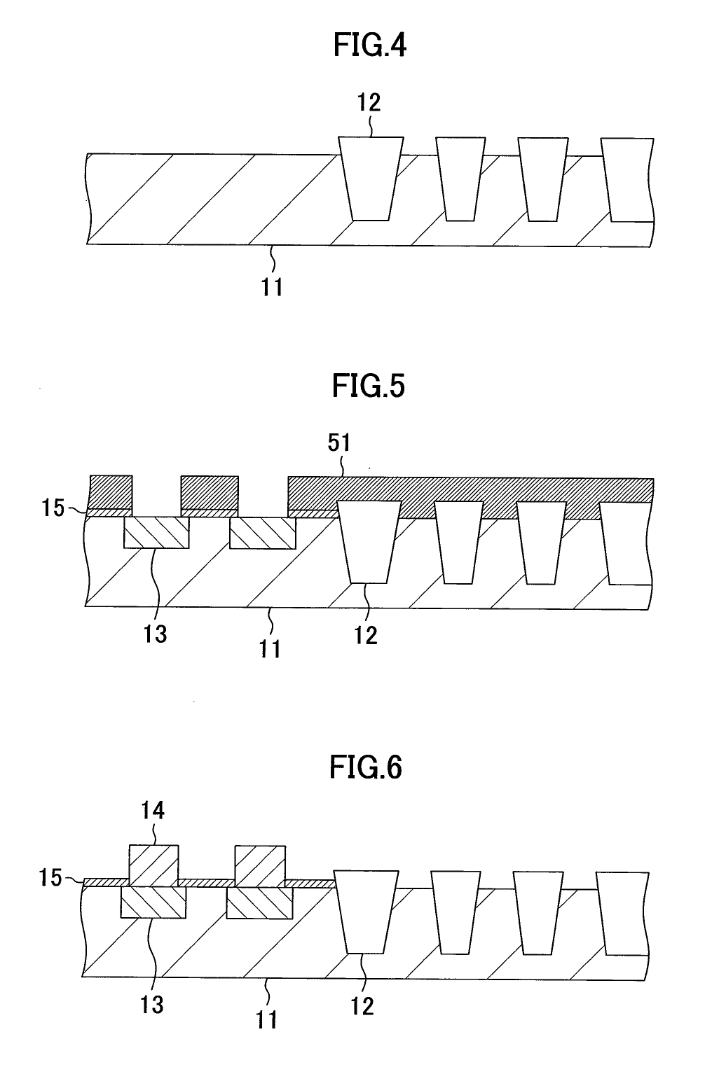

Next, a method for fabricating a semiconductor device of this embodiment will be described. FIGS. 4-11 illustrate sequential steps of a method for fabricating a semiconductor device of this embodiment.

First, as shown in FIG. 4, the semiconductor substrate 11 such as silicon is etched and trenches are formed, then the formed trenches are filled with a dielectric layer such as silicon oxide. The deposited dielectric layer is planarized by a chemical-mechanical polishing (CMP) technique, and the element isolation regions (STI portions) 12 are formed.

Next, as shown in FIG. 5, a trapping layer 15 with a thickness of 20 nm, made of an ONO layer, is deposited over the entire surface of the semiconductor substrate 11, and then the portion of the trapping layer 15 other than the memory cell region is selectively removed. After this, a mask formation layer with a thickness of about 50 nm-200 nm, made of silicon nitride, is deposited using, for example, a chemical vapor deposition (CVD) technique; and after a resist layer (not shown) is coated over the mask formation layer, opening patterns are formed in the resist layer to form openings in the portions which will subsequently be the source/drain regions 13 using a lithography technique. By performing a dry etching on the mask formation layer using the resist layer as a mask, a mask layer 51 having openings to form the source/drain regions 13 is formed. After this, the portions of the trapping layer 15 exposed through the openings are removed. Note that, since the trapping layer 15 is thin, these exposed portions may be used as protection layers for ion implantation, instead of being removed. The width of each opening is about 100 nm. This is to be the width of each source/drain region 13, and corresponds to the width of a bit line. Meanwhile, the width of the resist is about 150 nm, and corresponds to the channel width when a memory cell transistor is formed.

Next, the source/drain regions 13 are formed by ion implantation of, for example, an n-type impurity such as arsenic, using the mask layer 51. The ion implantation may be performed at one time or in two or more separate stages, and can be performed at an acceleration energy of 5 keV-200 keV at a dose of 1×10¹⁴ cm⁻²-1×10¹⁷ cm⁻².

Next, as shown in FIG. 6, in the openings of the mask layer 51, a buried dielectric layer made of silicon oxide is deposited using, for example, a high density plasma chemical vapor deposition (HDPCVD) technique, a low-pressure chemical vapor deposition (LPCVD) technique, etc. After this, excess portions of the silicon oxide layer external to the filled openings of the mask layer 51 are selectively removed using, for example, a CMP technique, an etch-back technique, etc. Then, only the mask layer 51 is selectively removed using a wet etching technique or an etch-back technique, thus the trapping layer 15 is exposed and the bit-line buried oxide layers 14 are formed. In doing so, by using a wet etching technique or an etch-back technique before or after the selective removal of the mask layer 51, the bit-line buried oxide layers 14 are arranged to have a height of about 50 nm.

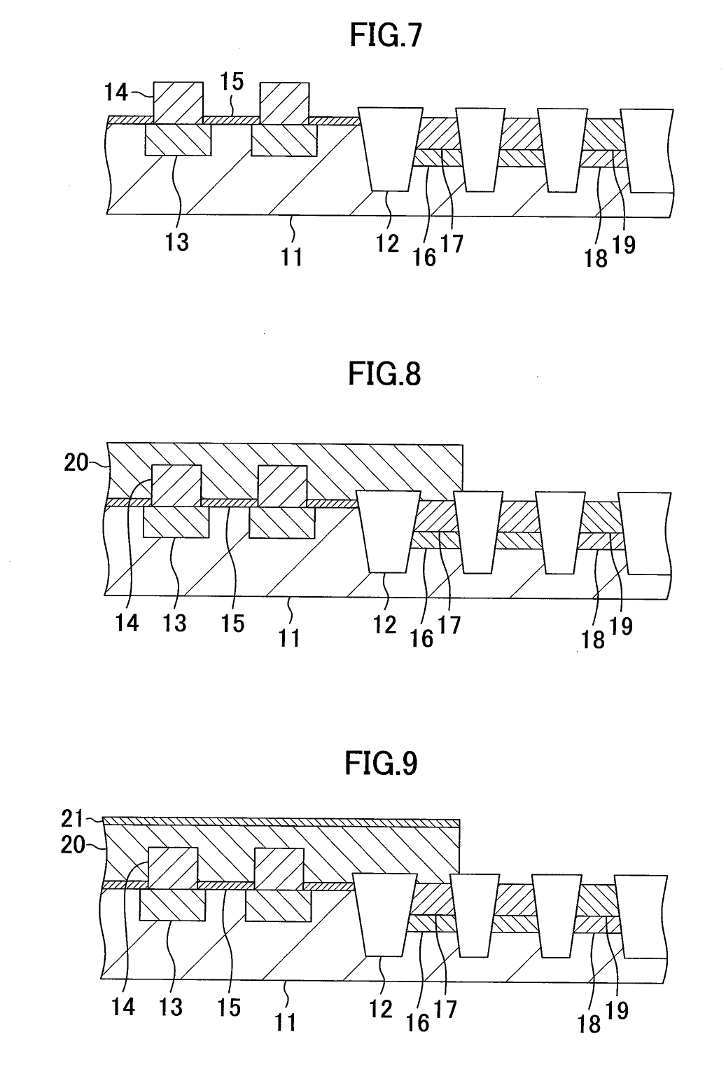

Next, as shown in FIG. 7, a p-type impurity diffusion layer 16 is formed by ion implantation of, for example, a p-type impurity such as boron, using a resist mask. The ion implantation may be performed at one time or in two or more separate stages, and can be performed at an acceleration energy of 5 keV-200 keV at a dose of 1×10¹⁴ cm⁻²-1×10¹⁷ cm⁻². Following this, using the same resist mask, an n-type impurity diffusion layer 17 is formed over the p-type impurity diffusion layer 16 by implanting, for example, an n-type impurity such as phosphorus. Formation of the n-type impurity diffusion layer 17 may also be performed at one time or in two or more separate stages, and can be performed at an acceleration energy of 5 keV-200 keV at a dose of 1×10¹⁴ cm⁻²-1×10¹⁷ cm⁻².

Then, after the resist mask is once removed, another resist mask is newly formed, and an n-type impurity diffusion layer 18 is formed by ion implantation of, for example, an n-type impurity such as phosphorus. Following this, using the same resist mask, a p-type impurity diffusion layer 19 is formed over the n-type impurity diffusion layer 18 by ion implantation of, for example, a p-type impurity such as boron. The condition for ion implantation of the n-type impurity diffusion layer 18 and the p-type impurity diffusion layer 19 can be the same as that of the n-type impurity diffusion layer 17 and the p-type impurity diffusion layer 16.

Next, as shown in FIG. 8, a polycrystalline silicon layer, doped to an n-type conductivity with phosphorus to a concentration in a range of approximately 1×10¹⁸ cm⁻³-1×10²² cm⁻³, is deposited over the entire surface of the semiconductor substrate 11 using, for example, a low-pressure chemical vapor deposition (LPCVD) technique. Then, after coating a resist layer, a resist pattern (not shown) is formed, using a lithography technique, to form a word line in a direction to intersect the source/drain formation regions disposed spaced apart from each other. After this, predetermined regions of the polycrystalline silicon layer are opened by dry etching, and a gate electrode 20 is formed. In doing so, the gate electrode 20 is formed so as to cover the n-type impurity diffusion layer 17, and to be connected to the n-type impurity diffusion layer 17.

Next, as shown in FIG. 9, a metal layer made of cobalt, nickel, etc., is deposited on the entire surface over the semiconductor substrate 11 using, for example, a vacuum deposition technique, etc., and then, a metal silicide layer 21 is formed over the gate electrode 20 by performing heat treatment. When the metal silicide layer 21 is formed, a protection layer is formed in advance to prevent silicidation of the n-type impurity diffusion layer 17 and the p-type impurity diffusion layer 19.

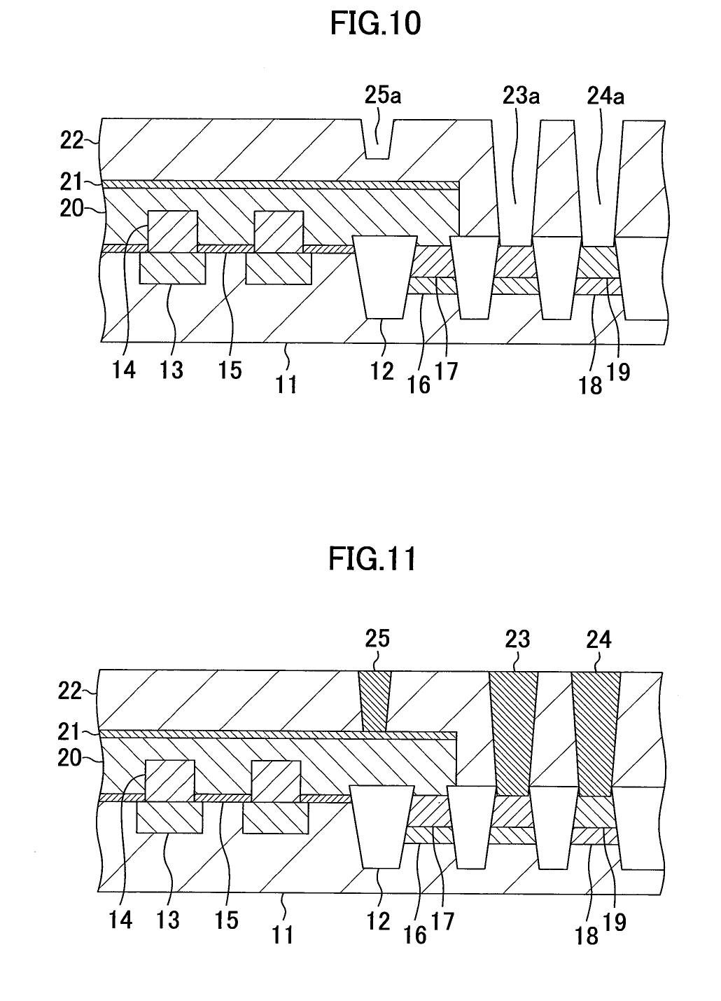

Next, as shown in FIG. 10, a dielectric layer made of silicon oxide is deposited on the entire surface over the semiconductor substrate 11 using, for example, an HDPCVD technique, an atmospheric-pressure chemical vapor deposition (APCVD) technique, a plasma-enhanced chemical vapor deposition (PECVD) technique, etc. After this, the surface is planarized using, for example, a CMP technique, a dry etch-back technique, etc., and an interlayer dielectric layer 22 is formed. Then, a contact opening 23a and a contact opening 24a to respectively expose the n-type impurity diffusion layer 17 and the p-type impurity diffusion layer 19, and a contact opening 25a to expose the gate electrode 20 are opened. The contact openings 23a and 24a are arranged to respectively reach the n-type impurity diffusion layer 17 and the p-type impurity diffusion layer 19 before the contact opening 25a reaches the gate electrode 20. FIG. 10 illustrates a situation in which the contact openings 23a and 24a have just reached the n-type impurity diffusion layer 17 and the p-type impurity diffusion layer 19, respectively, while the contact opening 25a has not yet reached the gate electrode 20.

In order that the contact openings 23a and 24a respectively reach the n-type impurity diffusion layer 17 and the p-type impurity diffusion layer 19 before the contact opening 25a reaches the gate electrode 20, microloading effects of dry etching can be used. More specifically, this can be achieved by ensuring that each of the opening areas of the contact openings 23a and 24a is greater than the opening area of the contact opening 25a. Alternatively, the contact opening 25a may be opened after the contact openings 23a and 24a have been opened using another mask.

Next, as shown in FIG. 11, a conductive layer made of a monolayer film made of, for example, tungsten, a tungsten compound, titanium, a titanium compound (e.g., titanium nitride), or of a multilayer film formed of a combination thereof, is deposited on the entire surface over the semiconductor substrate 11 so as to fill each contact opening, thus metal plugs are formed. Then, by removing portions of the conductive layer remaining over the interlayer dielectric layer 22 using a CMP technique, etc., a contact plug 23, a contact plug 24, and a contact plug 25 are formed. If each of the opening areas of the contact openings 23a and 24a is greater than the opening area of the contact opening 25a, each of the areas of the top surfaces of the contact plugs 23 and 24 will be greater than the area of the top surface of the contact plug 25.

As shown in FIG. 3B, the pn junction regions each formed of the p-type impurity diffusion layer 16 and the n-type impurity diffusion layer 17 form junction diodes D1 and D0, and the np junction region formed of the n-type impurity diffusion layer 18 and the p-type impurity diffusion layer 19 forms a junction diode D2. The junction diode D0 is connected to the gate electrode 20, and acts as a diode directly coupled to the substrate.

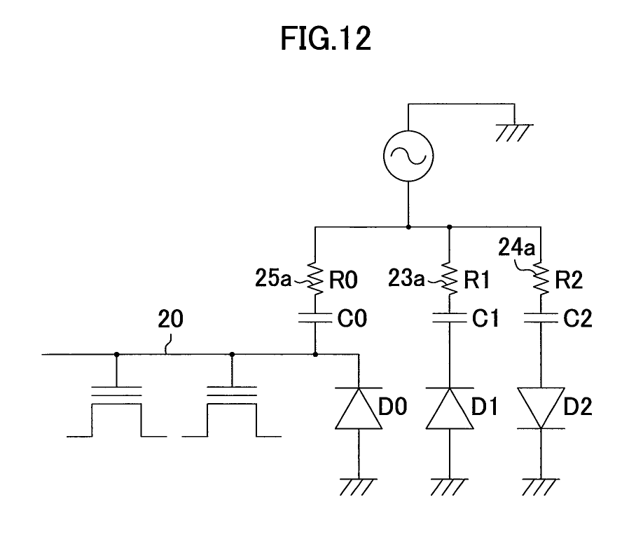

The equivalent circuit shown in FIG. 12 can explain how charge is accumulated in the gate electrode 20 when the contact opening 25a connected to the gate electrode 20, the contact opening 23a connected to the junction diode D1, and the contact opening 24a connected to the junction diode D2, are opened by dry etching.

As shown in FIG. 12, while dry etching is performed, a plasma source used for dry etching acts as an AC power supply, and each remaining layer of the interlayer dielectric layer 22 acts as a capacitor. That is, the remaining layer between the gate electrode 20 and the contact opening 25a acts as a capacitor C0, the remaining layer between the junction diode D1 and the contact opening 23a acts as a capacitor C1, and the remaining layer between the junction diode D2 and the contact opening 24a acts as a capacitor C2. In addition, the contact opening 25a acts as a resistor R0, the contact opening 23a acts as a resistor R1, and the contact opening 24a acts as a resistor R2.

According to this equivalent circuit, while dry etching is performed, the capacitor C0, the capacitor C1, and the capacitor C2 each experiences a change in the capacitance depending on the material and the remaining layer thickness of the interlayer dielectric layer 22, thus charge is accumulated. Since the capacitor C0 is connected to the gate electrode 20, the charge accumulated in the capacitor C0 is trapped in the trapping layer 15. According to a circuit simulation, a condition for a case where charge is less likely to be accumulated in the capacitor C0 can be expressed using Equations (1) and (2) as follows:

(C0>C1 and C0>C2) and (R0<R1 and R0<R2) (1)

(C1=C2=0) and (R0<R1 and R0<R2) (2)

Note that according to the circuit simulation, the amount of charge accumulated in the gate electrode 20 is reduced by forming a protection diode to approximately one-half that of a case without a protection diode.

According to the method for fabricating a semiconductor device of this embodiment, the contact openings 23a and 24a respectively reach the n-type impurity diffusion layer 17 and the p-type impurity diffusion layer 19 before the contact opening 25a reaches the gate electrode 20. Therefore, the condition of Equation (1) can be satisfied until the contact openings 23a and 24a respectively reach the junction diodes D1 and D2. Also, the condition of Equation (2) can be satisfied during a period from when the contact openings 23a and 24a respectively reach the junction diodes D1 and D2 until the contact opening 25a reaches the gate electrode 20. Accordingly, the charge generated during plasma etching to form the contact openings is dissipated mainly to the protection diodes D1 and D2, thereby minimizing the amount of charge accumulated in the gate electrode 20 side.

In this embodiment, even though silicon nitride is used as the mask layer 51 to form the source/drain regions 13, a dielectric layer made of a silicon compound such as silicon oxide may be used, instead of silicon nitride. In addition, when the source/drain regions 13 are formed, a resist material may be used as a mask, instead of using a mask layer made of a silicon compound.

In this embodiment, even though a multilayer film formed of silicon oxide, silicon nitride, and silicon oxide is used as a trapping layer 15 having a charge-trapping site, a monolayer film made of silicon oxynitride; a monolayer film made of silicon nitride; a multilayer film formed of silicon oxide layer and silicon nitride layer deposited sequentially from the semiconductor substrate side; a multilayer film formed of silicon oxide, silicon nitride, silicon oxide, silicon nitride, and silicon oxide deposited sequentially, etc., may instead be used.

In this embodiment, even though the description has been provided for an example in which the layer thickness of the trapping layer 15 is 20 nm, the layer thickness may be selected from a range of 10 nm-30 nm as appropriate so that the characteristics of the transistor is optimized. Also, even though the height of the buried oxide layers has been described as 50 nm, the height may be selected from a range of 20 nm-100 nm as appropriate so that a leakage current between the gate electrode and a source/drain is optimized. Furthermore, even though the width of the source/drain regions 13 has been described as 100 nm, the width may be selected from a range of 30 nm-300 nm as appropriate by optimizing the characteristics of the transistor.

In this embodiment, even though a resist material is used for a mask for dry etching of the polycrystalline silicon layer from which the gate electrode will be formed, it is conceivable that a high etch selectivity ratio is required in a process for high degree of integration, and in such a case, the mask may be a mask made of silicon oxide, silicon nitride, or a multilayer mask formed of these material layer and a resist material. In addition, even though a monolayer film is used for the polycrystalline silicon layer from which the gate electrode will be formed, the polycrystalline silicon layer may be made of a multilayer film formed of a plurality of polycrystalline silicon layers. Also, even though the description has been provided for an example in which the polycrystalline silicon layer forming the gate electrode is deposited as a doped polysilicon layer, another doping approach may be such that impurity is implanted after depositing undoped polycrystalline silicon which has not been doped with impurity. The gate electrode may be a monolayer film made of polycrystalline silicon (polysilicon), amorphous silicon, refractory metal having a melting point of 600° C. or above, such as tantalum, titanium, etc., a metal compound, or a metal silicide, or a multilayer film formed of a combination thereof. In addition, a polycrystalline silicon layer forming the word line (the gate electrode 20) may be silicided with a metal.

In this embodiment, even though the description has been provided in terms of a memory device whose source/drain regions are n-type, the present disclosure can also be applied to a p-type memory device. A p-type impurity diffusion layer having a lower impurity concentration than that of the n-type impurity diffusion layer may be formed so as to cover a sidewall and a bottom of the n-type impurity diffusion layer which is a part of the source/drain regions 13. With this configuration, short channel effects, caused by diffusion of impurity of the n-type impurity diffusion layer, can be avoided by the p-type impurity diffusion layer, thereby reducing a space between a pair of the source/drain regions 13. That is, a gate length can be reduced, thereby allowing for a semiconductor device having a smaller feature size.

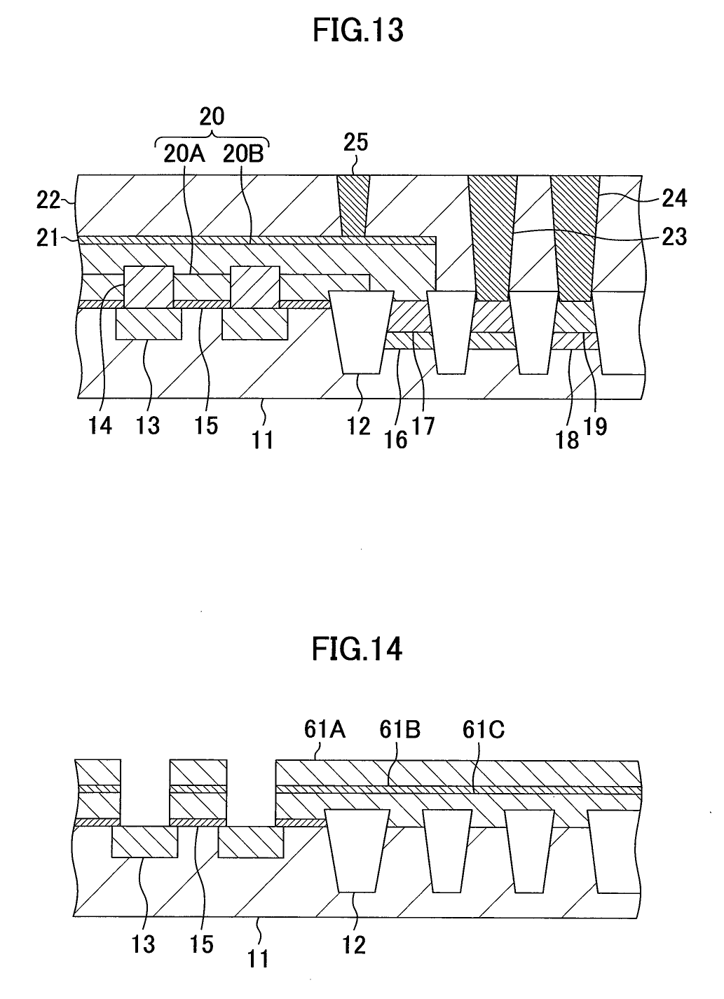

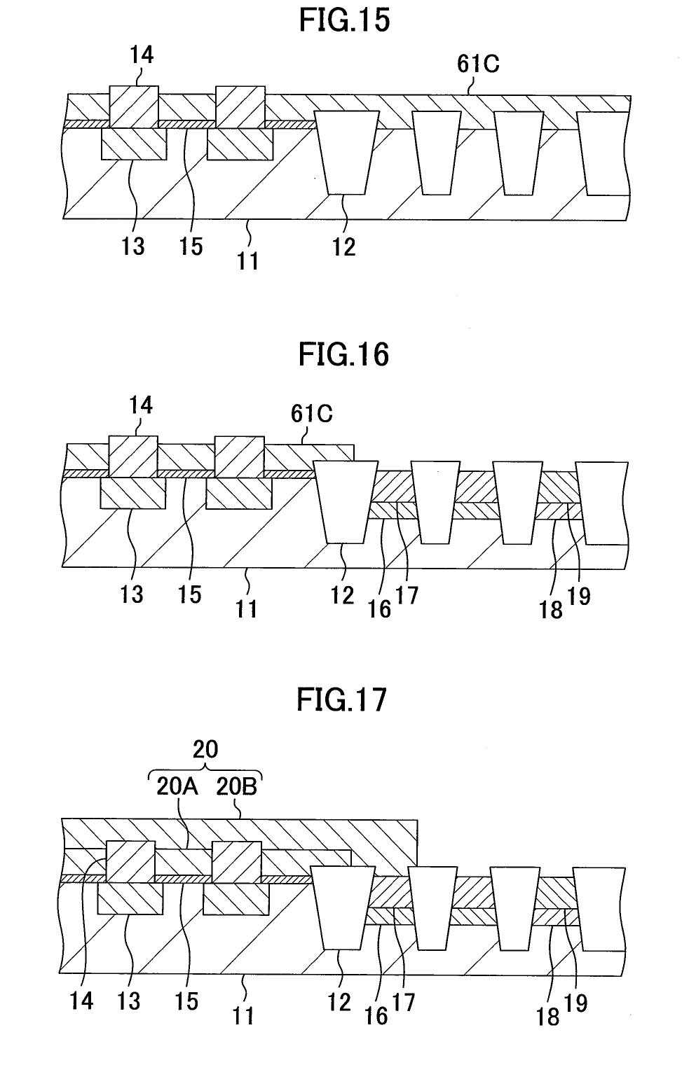

In the semiconductor device of this embodiment, as shown in FIG. 13, a gate electrode 20 may have only in a memory cell a configuration such that a first polycrystalline silicon layer 20A and a second polycrystalline silicon layer 20B are stacked. In order to implement this configuration, after the step shown in FIG. 5, openings to form buried oxide layers are formed in a multilayer film formed of silicon nitride 61A, silicon oxide 61B, and polycrystalline silicon 61C as shown in FIG. 14. Next, as shown in FIG. 15, the silicon nitride 61A and the silicon oxide 61B are removed. Then, as shown in FIG. 16, the polycrystalline silicon 61C is removed in the diode formation region. After this, as shown in FIG. 17, the polycrystalline silicon layer 20B is formed so as to cover the polycrystalline silicon layer 61C, thus the gate electrode 20 in which the polycrystalline silicon layer 20A and the polycrystalline silicon layer 20B are stacked is formed. With this configuration, the planarity of the surface of the polycrystalline silicon layer from which the gate electrode will be formed is improved, thereby allowing for process with high accuracy of gate dimension.

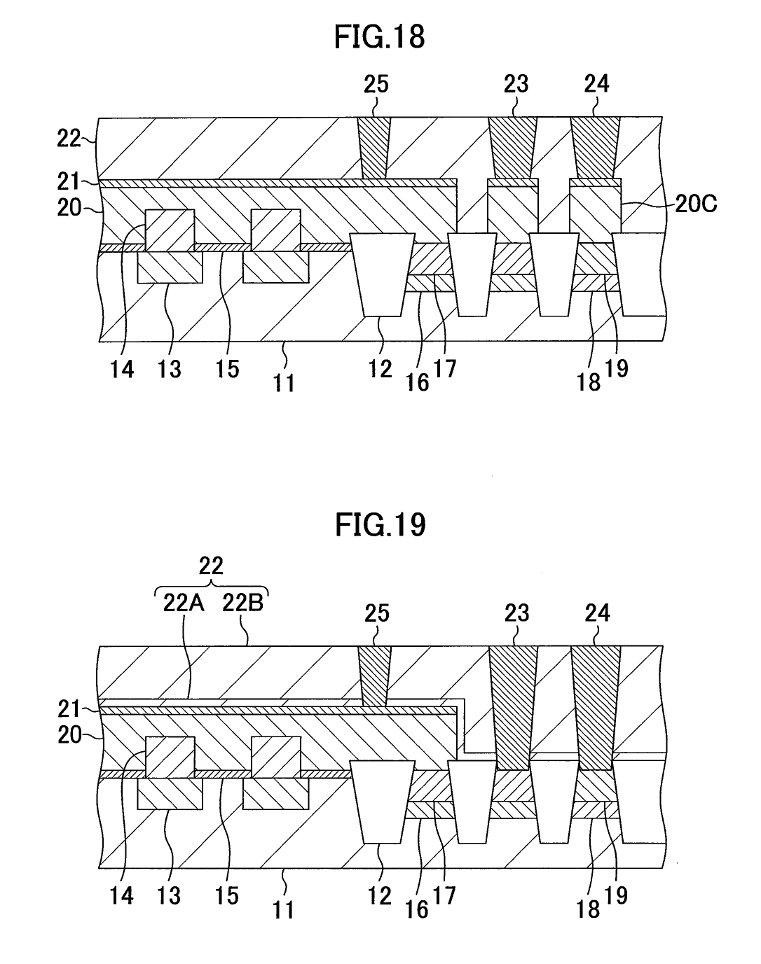

In addition, as shown in FIG. 18, the polycrystalline silicon layer, which is a same material as the gate electrode 20, may be formed over the diode D1 and the diode D2. In order to implement this configuration, when the gate electrode 20 is formed in FIG. 8, pattern of the gate electrode can also be formed over the diode D1 and the diode D2. In this case, the layer thickness of the conductive layer 20C formed over the diode D1 and the diode D2 is the same as that of the gate electrode 20. With this configuration, the aspect ratios of the contact openings can be reduced in forming the contact openings for connection with interconnects, thereby allowing for process with high accuracy of opening dimension.

In addition, as shown in FIG. 19, the interlayer dielectric layer 22 may have a two-layer stacked configuration made of a liner layer 22A and a dielectric layer 22B. One approach for implementing this configuration is to first deposit the liner layer 22A on the entire surface over the semiconductor substrate 11 of FIG. 9, and then to deposit the dielectric layer 22B thereover. With this configuration, digging damage in an underlying silicon layer, etc., is reduced during forming the contact openings for connection with interconnects, thereby allowing for process with high accuracy of opening dimension.

Note that, in this embodiment, the configurations shown in FIGS. 13, 18, and 19 can be applied in combination. The following configurations may be used:

(a) a two-layer gate electrode in a memory cell+a gate electrode over a diode

(b) a two-layer gate electrode in a memory cell+a liner layer

(c) a gate electrode over a diode+a liner layer

(d) a two-layer gate electrode in a memory cell+a gate electrode over a diode+a liner layer

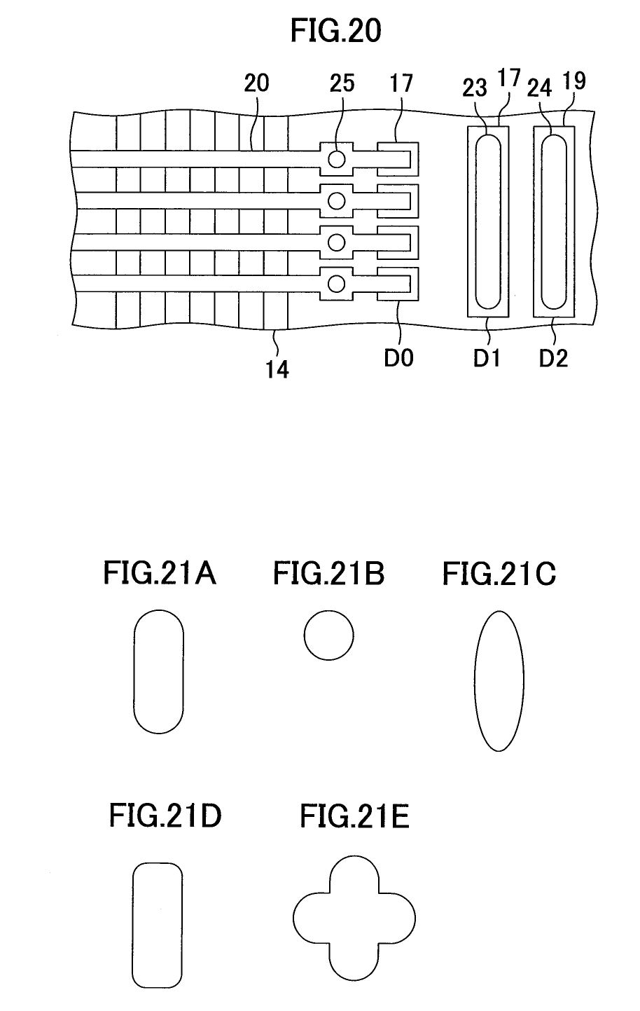

When a plurality of semiconductor elements are integrated, it is sufficient that multiple ones of the protection diode be disposed along the outer periphery of an array in which the semiconductor elements (here, semiconductor memories) are disposed collectively. Furthermore, it is preferable that, as shown in FIG. 20, the diodes D1 and D2 be disposed adjacent to the memory cell region. In FIG. 20, the planar shape of the contact plugs 23 and 24 is a rectangle with a semicircle at each end (an elongated circle) as shown in FIG. 21A. However, as far as the area of the top surface thereof is greater than that of the contact plug 25, any shape can be successfully applied. For example, a true circle of FIG. 21B, an elongated ellipse of FIG. 21C, a rectangle with rounded corners of FIG. 21D, a combination of two elongated circles as shown in FIG. 21E, etc., may be used.

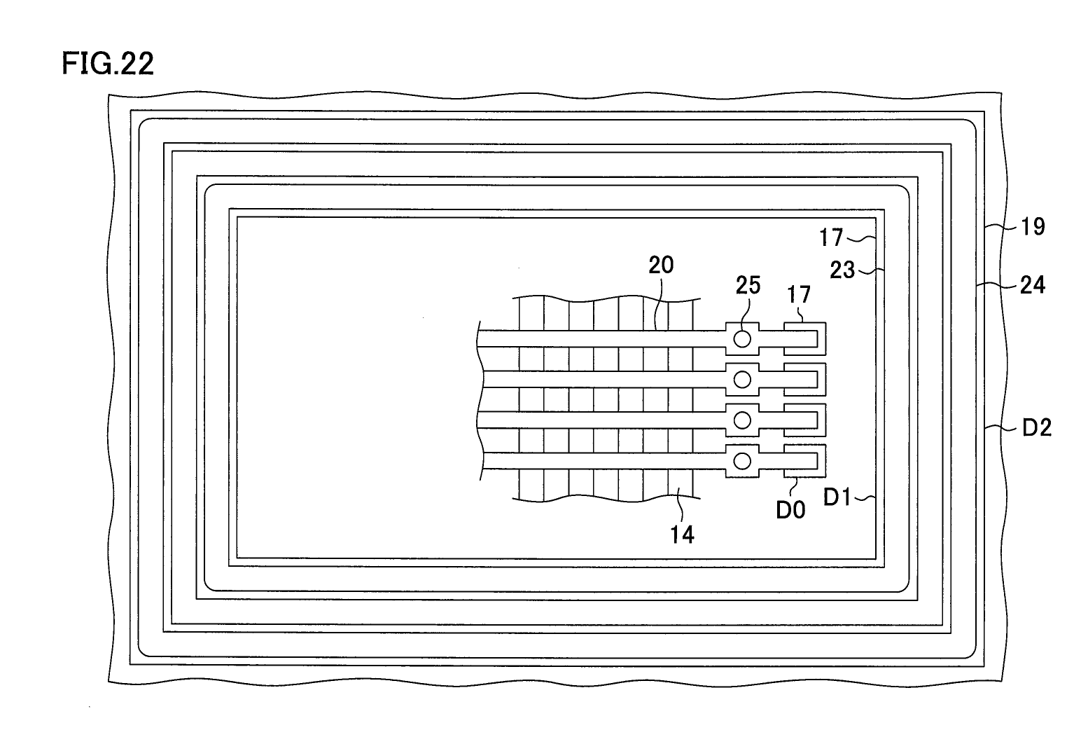

As shown in FIG. 22, in order to save the area to dispose the diodes D1 and D2, seal ring portions formed to surround the semiconductor chip may respectively be formed as common components with the diode D1, which has a stacked configuration of a p-type impurity diffusion layer (not shown) and an n-type impurity diffusion layer 17, and with the diode D2, which has a stacked configuration of an n-type impurity diffusion layer (not shown) and a p-type impurity diffusion layer 19. In this case, the planar shape of the contact plugs 23 and 24 may be a ring.

### Second Embodiment

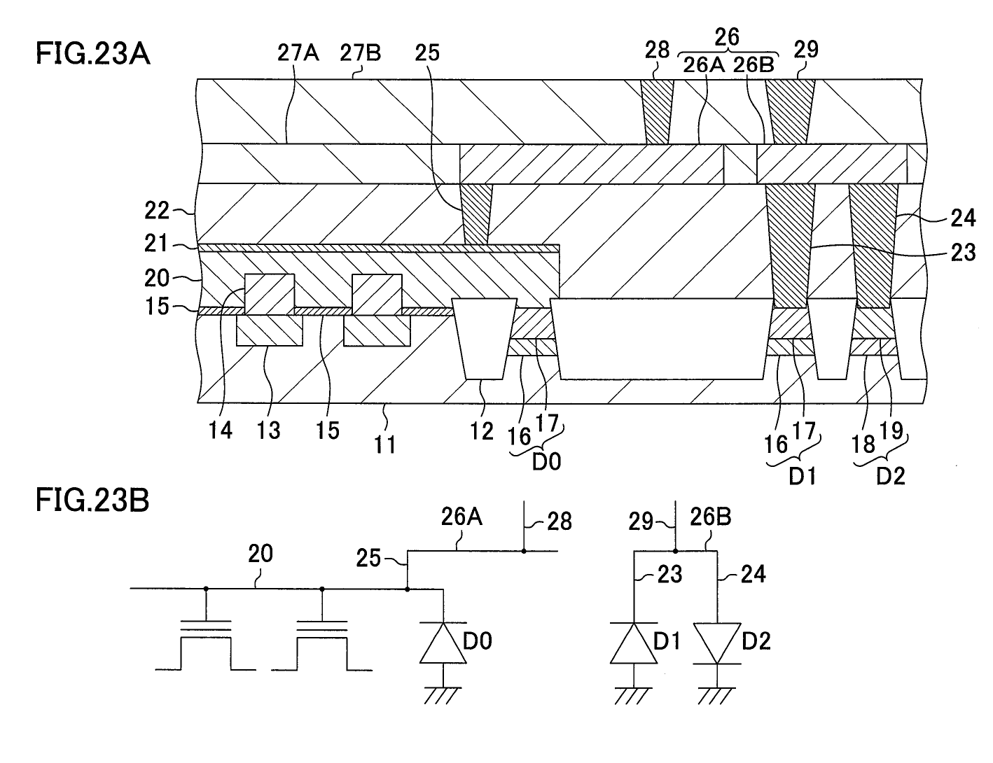

The second embodiment will now be described with reference to the drawings. FIGS. 23A and 23B illustrate a semiconductor device in accordance with the second embodiment. FIG. 23A shows a cross-sectional configuration thereof, and FIG. 23B shows a circuit configuration thereof. In FIGS. 23A and 23B, like reference characters indicate the same or similar components to those of FIGS. 3A and 3B, and the explanation thereof will be omitted.

Similar to the first embodiment, the semiconductor device of this embodiment may also include multiple ones of the semiconductor element 1, but the following description will be provided in terms of that including a single semiconductor element 1.

As shown in FIGS. 23A and 23B, in this embodiment, an interlayer dielectric layer 27A and a first-layer interconnect 26 is formed over the interlayer dielectric layer 22 including the contact plugs 23, 24, and 25. The first-layer interconnect 26 is formed in a layer at the same level as the interlayer dielectric layer 27A. The contact plug 25 is connected to a first interconnect segment 26A of the first-layer interconnect 26, and the contact plugs 23 and 24 are connected to a second interconnect segment 26B of the first-layer interconnect 26, which is electrically isolated from the first interconnect segment 26A. Over the interlayer dielectric layer 27A and the first-layer interconnect 26, an interlayer dielectric layer 27B is formed. Over the interlayer dielectric layer 27B, a second-layer interconnect (not shown) is formed. The first interconnect segment 26A and the second-layer interconnect are connected through a via plug 28, and the second interconnect segment 26B and the second-layer interconnect are connected through a via plug 29. The via plug 28 is connected to the gate electrode 20 in the memory cell through both the first interconnect segment 26A and the contact plug 25. The via plug 29 is connected to the pn junction region through both the second interconnect segment 26B and the contact plug 23, and to the np junction region through both the second interconnect segment 26B and the contact plug 24. The area of the top surface of the via plug 29 connected to the pn junction region and to the np junction region is greater than the area of the top surface of the via plug 28 connected to the gate electrode 20 in the memory cell.

Next, a method for fabricating a semiconductor device of the second embodiment will be described with reference to the drawings. The method of this embodiment is the same as that of the first embodiment until the contact plugs 23, 24, and 25 connected to the first-layer interconnect 26 are formed. A duplicated explanation of these fabrication steps will be omitted.

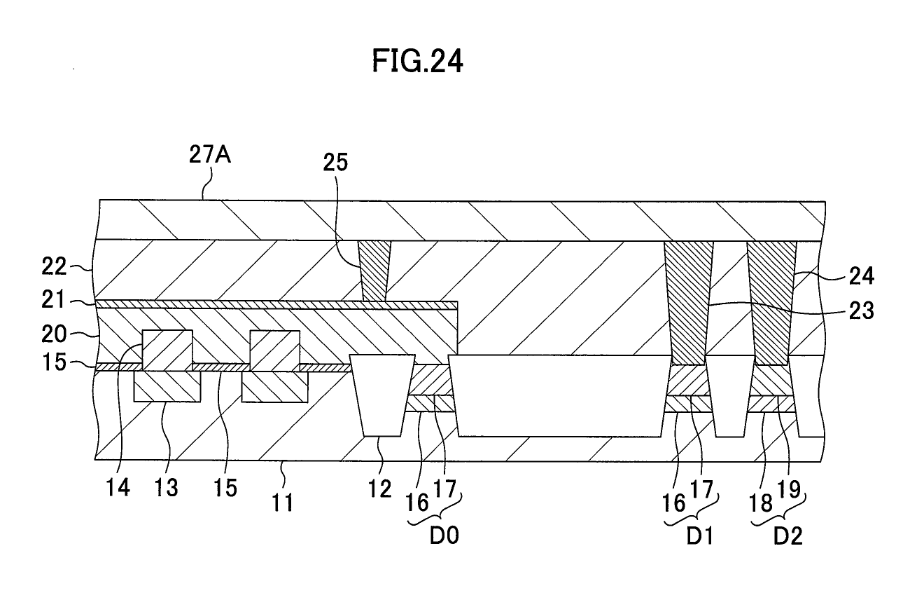

After the contact plugs 23, 24, and 25 have been formed, as shown in FIG. 24, an interlayer dielectric layer 27A, made mainly of silicon oxide, is deposited on the entire surface over the semiconductor substrate 11 using, for example, an HDPCVD technique, an APCVD technique, a PECVD technique, etc.

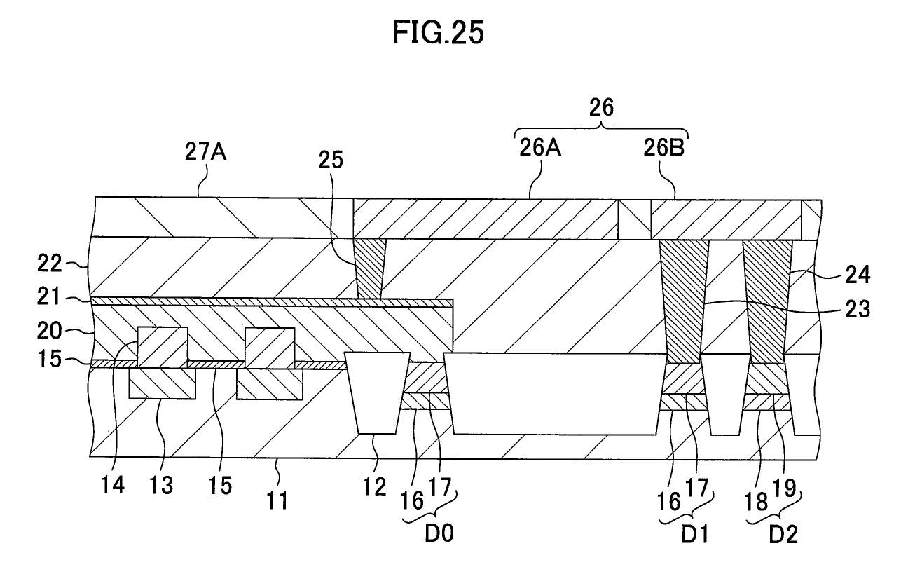

Next, as shown in FIG. 25, trench portions to form the first interconnect segment 26A and the second interconnect segment 26B of the first-layer interconnect 26 are formed by dry etching, and metal to be formed as interconnects is deposited to fill the trench portions using a plating technique, a physical vapor deposition (PVD) technique, etc. After this, excess metal is removed using a dry etch-back technique or a CMP technique, and the first interconnect segment 26A and the second interconnect segment 26B in a buried configuration are formed. The first-layer interconnect 26 may be a film made of a material selected from the group consisting of silicon, tungsten, titanium, titanium nitride, aluminum, copper, tantalum, ruthenium, vanadium, or manganese, or a compound thereof; a multilayer film formed of either aluminum or an aluminum compound, titanium, and titanium nitride; or a multilayer film formed of either copper or a copper compound, tantalum, and tantalum nitride, etc.

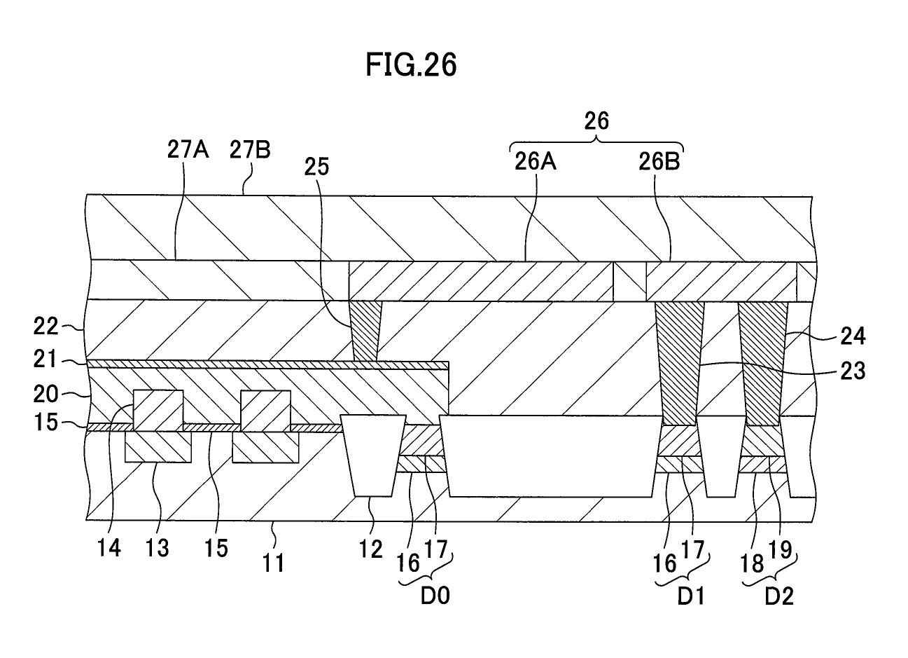

Next, as shown in FIG. 26, an interlayer dielectric layer 27B, made mainly of silicon oxide, is deposited on the entire surface over the semiconductor substrate 11 using, for example, an HDPCVD technique, an APCVD technique, a PECVD technique, etc.

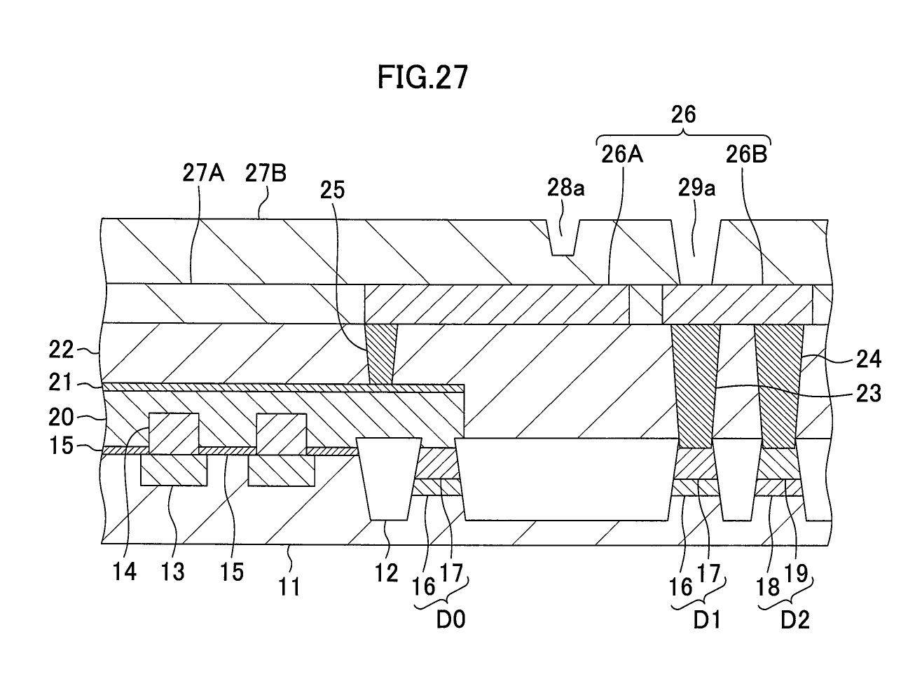

Next, as shown in FIG. 27, a contact opening 28a, which exposes the first interconnect segment 26A connected to the gate electrode 20, and a contact opening 29a, which exposes the second interconnect segment 26B connected to the diodes D1 and D2, are formed in the interlayer dielectric layer 27B. The contact opening 29a is arranged to reach the second interconnect segment 26B before the contact opening 28a reaches the first interconnect segment 26A. FIG. 27 illustrates a situation in which the contact opening 29a has just reached the second interconnect segment 26B, while the contact opening 28a has not yet reached the first interconnect segment 26A.

In order that the contact opening 29a reaches the second interconnect segment 26B before the contact opening 28a reaches the first interconnect segment 26A, microloading effects of dry etching can be used. More specifically, this can be achieved by ensuring that the opening area of the contact opening 29a is greater than the opening area of the contact opening 28a. Alternatively, the contact opening 28a may be opened after the contact opening 29a has been opened using another mask.

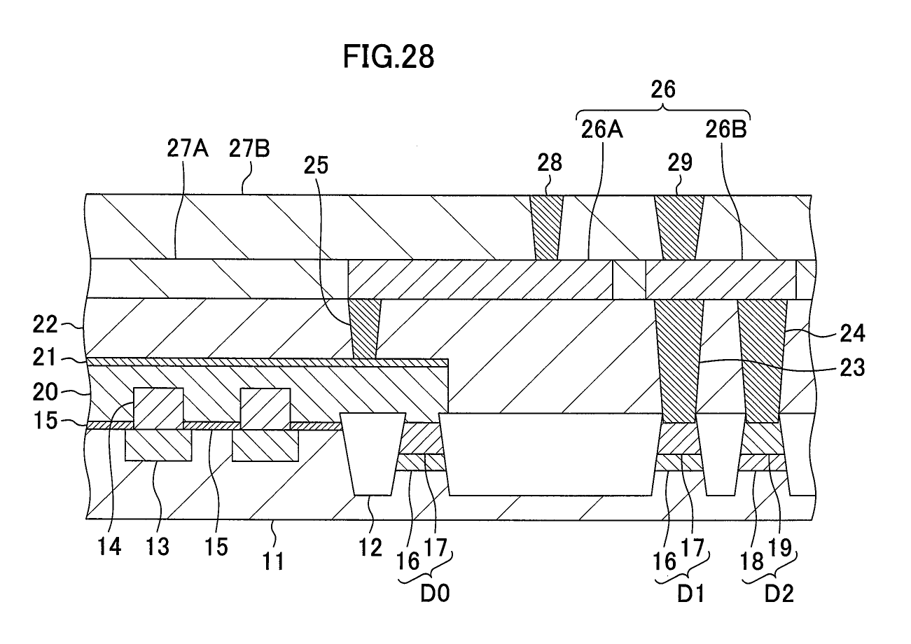

Next, as shown in FIG. 28, a conductive layer made of a metal monolayer film made of, for example, tungsten, a tungsten compound, titanium, or a titanium compound, or of a multilayer film of a combination thereof, etc., is deposited on the entire surface over the semiconductor substrate 11 so as to fill each contact opening, thus metal plugs are formed. Then, by removing portions of the conductive layer remaining over the interlayer dielectric layer 27B using a CMP technique, etc., a via plug 28 and a via plug 29 are formed. If the opening area of the contact opening 29a is greater than the opening area of the contact opening 28a, the area of the top surface of the via plug 29 will be greater than the area of the top surface of the via plug 28.

As shown in FIG. 23B, the pn junction regions each formed of the p-type impurity diffusion layer 16 and the n-type impurity diffusion layer 17 form junction diodes D0 and D0, and the np junction region formed of the n-type impurity diffusion layer 18 and the p-type impurity diffusion layer 19 forms a junction diode D2. The junction diode D0 is connected to the gate electrode 20, and acts as a diode directly coupled to the substrate.

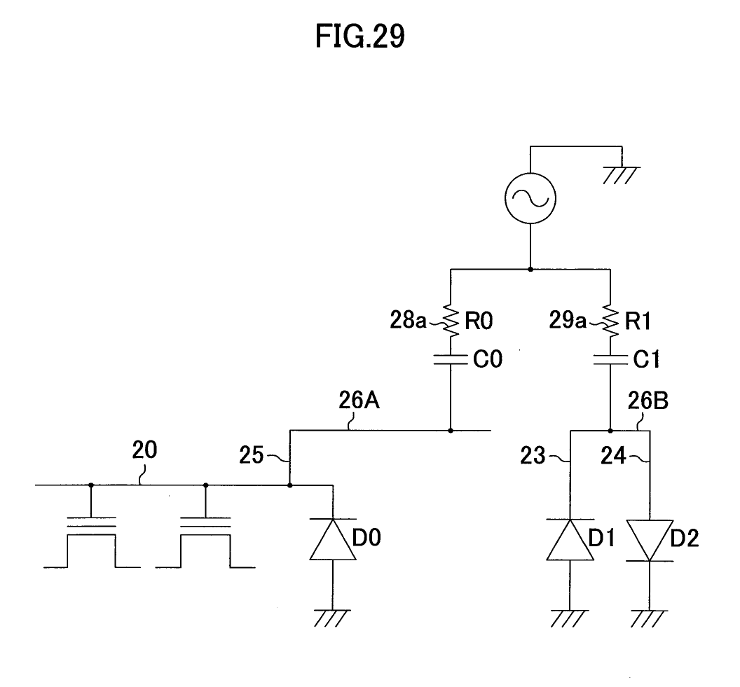

The equivalent circuit shown in FIG. 29 can explain how charge is accumulated in the gate electrode 20 while the contact opening 28a to expose the first interconnect segment 26A connected to the memory cell, and the contact opening 29a to expose the second interconnect segment 26B connected to the junction diodes D1 and D2, are opened by dry etching.

As shown in FIG. 29, while dry etching is performed, a plasma source used for dry etching acts as an AC power supply, and each remaining layer of the interlayer dielectric layer 27B acts as a capacitor. That is, the remaining layer between the first interconnect segment 26A and the contact opening 28a acts as a capacitor C0, and the remaining layer between the second interconnect segment 26B and the contact opening 29a acts as a capacitor C1. In addition, the contact opening 28a acts as a resistor R0, and the contact opening 29a acts as a resistor R1.

According to this equivalent circuit, while dry etching is performed, the capacitor C0 and the capacitor C1 each experiences a change in the capacitance depending on the material and the remaining layer thickness of the interlayer dielectric layer, and charge is accumulated. Since the capacitor C0 is connected to the gate electrode 20 through the first interconnect segment 26A, the charge accumulated in the capacitor C0 is trapped in the trapping layer 15. According to a circuit simulation, a condition for a case where charge is less likely to be accumulated in the capacitor C0 can be expressed using Equations (3) and (4) as follows:

(C0>C1) and (R0<R1) (3)

(C1=0) and (R0<R1) (4)

Note that according to the circuit simulation, the amount of charge accumulated in the gate electrode 20 is reduced by forming a protection diode to approximately one-half that of a case without a protection diode.

According to the method for fabricating a semiconductor device of this embodiment, the contact opening 29a reaches the second interconnect segment 26B before the contact opening 28a reaches the first interconnect segment 26A. Therefore, the condition of Equation (3) can be satisfied until the contact opening 29a reaches the second interconnect segment 26B. Also, the condition of Equation (4) can be satisfied during a period from when the contact opening 29a reaches the second interconnect segment 26B until the contact opening 28a reaches the first interconnect segment 26A. Accordingly, the charge generated during plasma etching to form the contact openings is dissipated mainly to the protection diodes D1 and D2, thereby minimizing the amount of charge accumulated in the gate electrode 20 side.

Also in the second embodiment, same or similar modifications to materials and dimensions as is described for the first embodiment may be applied. In addition, a variation as shown in FIG. 13, FIG. 18, or FIG. 19, or any combination thereof may be applied.

In the second embodiment, the description of the interlayer dielectric layers 27A and 27B has been provided in terms of monolayer films, but the interlayer dielectric layers 27A and 27B may each be a multilayer film formed of a liner layer and a dielectric layer. Alternatively, a multilayer film formed of a low-permittivity layer and a metal diffusion barrier layer may be used. Specific examples include a multilayer film formed of a silicon oxide layer including fluorine, a silicon nitride layer, and a silicon oxide layer; and a multilayer film formed of a silicon oxide layer including carbon, a silicon carbide layer including nitrogen, and a silicon carbide layer including oxygen, etc.

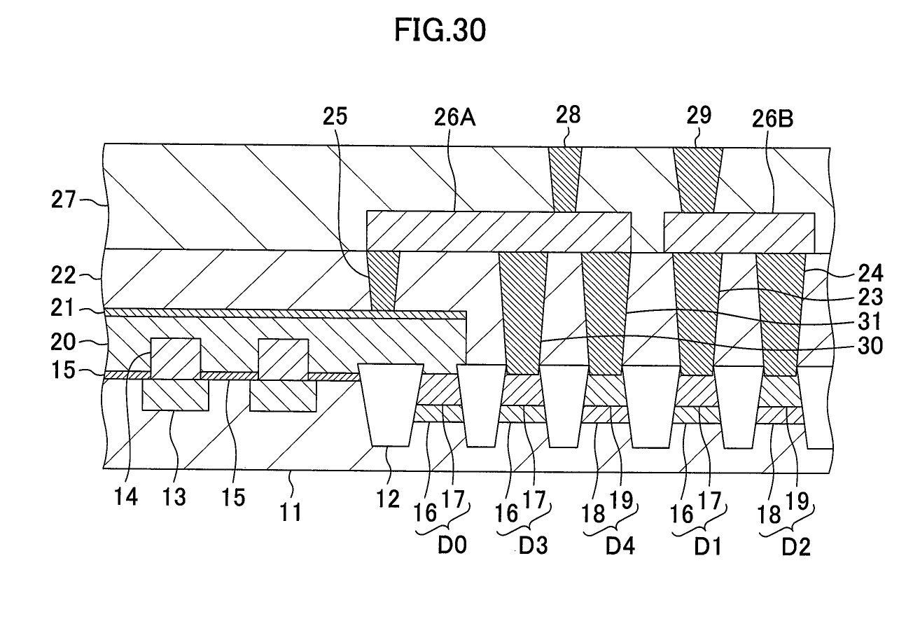

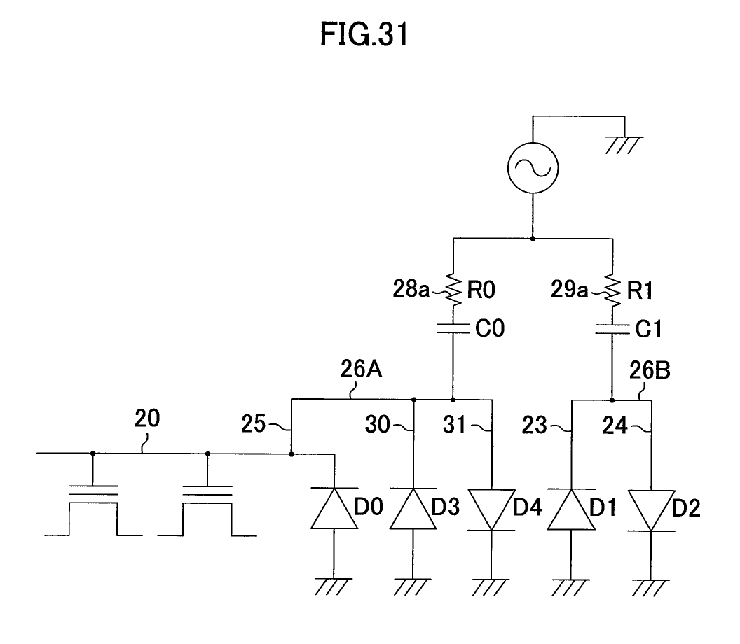

In this embodiment, as shown in FIG. 30, the semiconductor device may have a configuration in which the first interconnect segment 26A, connected to the gate electrode 20 in the memory cell, is connected to a diode D3 and a diode D4, which respectively act in a same manner as the diode D1 and the diode D2. Since this configuration provides an equivalent circuit as shown in FIG. 31, the amount of charge accumulated in the trapping layer 15 by dry etching to form the first-layer interconnect 26 is reduced, and in addition, excess charge, which has not flown to the side of the diodes D1 and D2, and accumulated in the capacitor C0 while the contact opening 28a is formed, is less likely to flow into the gate electrode 20 side.

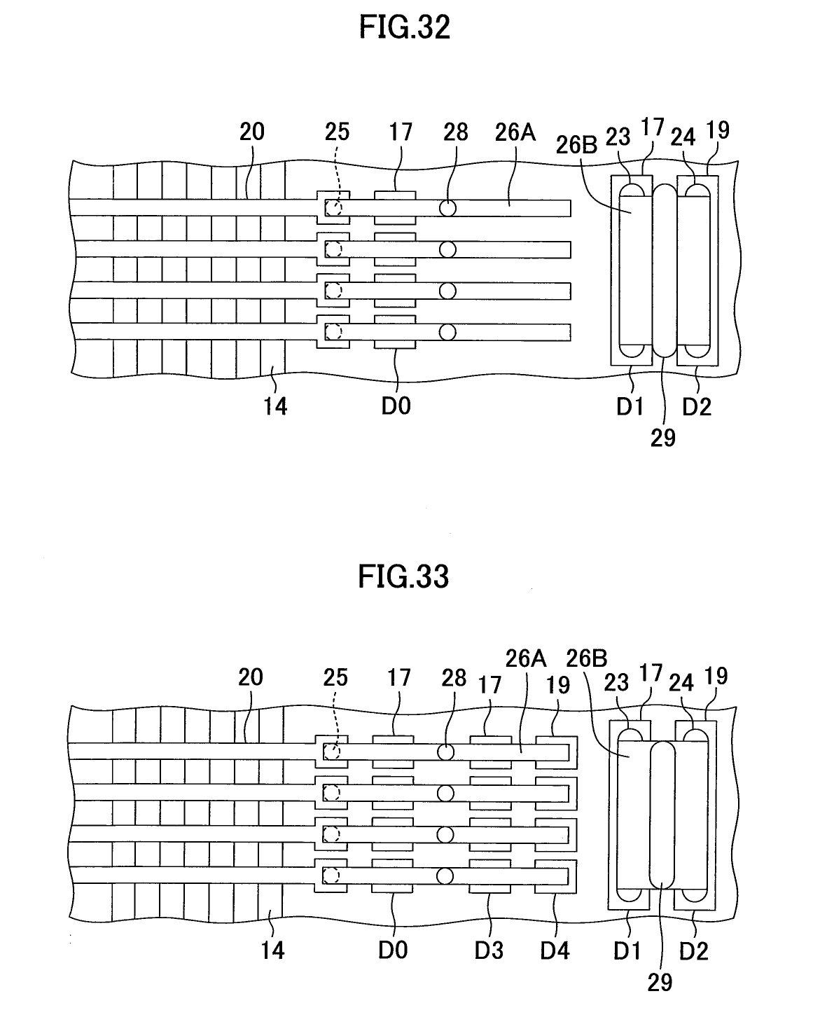

FIG. 32 is a top view illustrating an example of the semiconductor device in accordance with the second embodiment. As shown in FIG. 32, it is preferable that the diodes D1 and D2 be disposed adjacent to the memory cell region. If the diodes D3 and D4 are provided, a layout shown in FIG. 33 may be used.

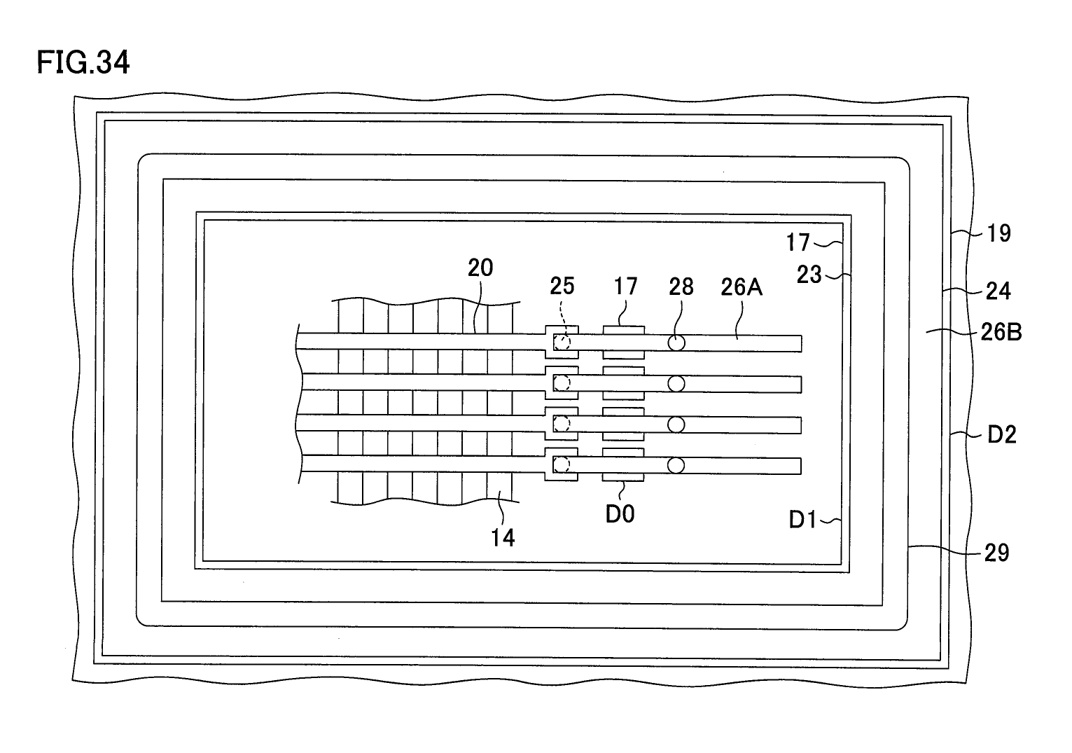

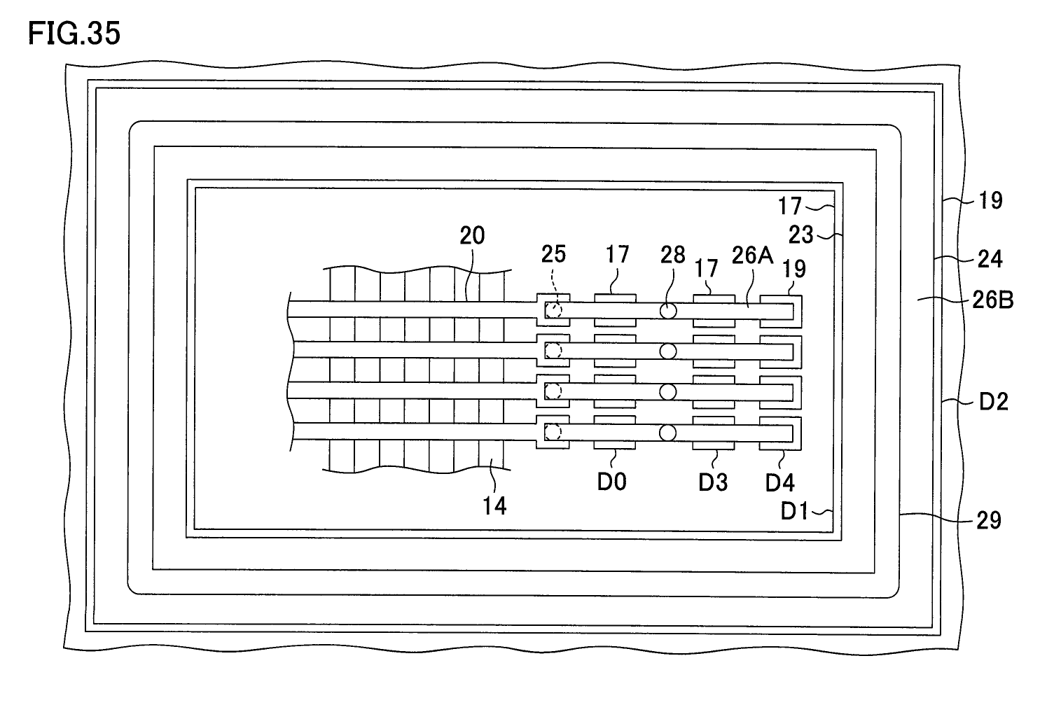

Also in this embodiment, as with the case of the first embodiment, seal ring portions formed to surround the semiconductor chip may respectively be formed as common components with the diodes D1 and D2 as shown in FIG. 34 or FIG. 35, in order to save the area to dispose the diodes D1 and D2.

Also, the planar shape of the via plug 29 is not limited to a rectangle with a semicircle at each end (an elongated circle). As far as the area of the top surface thereof is greater than that of the via plug 28, any shape can be used; as with the case of the first embodiment, a true circle, an elongated ellipse, a rectangle with rounded corners, a combination of two elongated circles, etc., may be used.

Even though the description of this embodiment has been provided in terms of interconnects disposed in two layers, the present invention can also be applied to a semiconductor memory device which includes interconnects disposed in more than two layers.

Furthermore, even though the foregoing description has been provided employing a non-volatile semiconductor memory device called flash memory as an example for each embodiment, the present invention is not limited thereto, and can be applied to any highly integrated similar semiconductor memory device which is affected by charge accumulation. A same or similar configuration can be applied to, for example, a volatile semiconductor memory, such as a DRAM, and to a non-volatile semiconductor memory, such as an MRAM, a RRAM, a FRAM, and a PRAM. In addition, since the present invention provides a capability to significantly reduce the effects of charge accumulation in a gate electrode, the present invention can be applied to the entire range of semiconductor devices including highly integrated semiconductor logic devices in a similar manner.

As is discussed above, the semiconductor devices and the methods for fabricating the same of the present disclosure can achieve a semiconductor device which prevents accumulation of a small amount of charge insufficient to cause breakdown; and are useful as, among others, a non-volatile semiconductor memory which stores electrical charge in a trapping layer, and a method for fabricating the same, etc.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A semiconductor device, comprising:
a semiconductor element and a protection diode both formed on a semiconductor substrate;
a first interlayer dielectric layer formed over the semiconductor substrate so as to cover the semiconductor element and the protection diode;
a first plug formed in the first interlayer dielectric layer and electrically connected to the semiconductor element; and
a second plug formed in the first interlayer dielectric layer and electrically connected to the protection diode, wherein
the area of the top surface of the second plug is greater than the area of the top surface of the first plug.

2. The semiconductor device of claim 1, wherein
the planar shape of the second plug is a circle or an elongated circle.

3. The semiconductor device of claim 2, wherein
the elongated circle is an elongated circle with a length ratio of long side to short side of more than or equal to 2.

4. The semiconductor device of claim 1, wherein
the semiconductor element is a non-volatile semiconductor memory which stores electrical charge in a trapping layer, or a non-volatile semiconductor memory which stores electrical charge in a floating electrode.

5. The semiconductor device of claim 4, wherein
the semiconductor element has a buried bit-line configuration.

6. The semiconductor device of claim 1, wherein
the protection diode includes a diode element directly coupled to the substrate, and
a gate electrode of the semiconductor element is connected to the diode element directly coupled to the substrate.

7. The semiconductor device of claim 1, wherein
the protection diode includes a first protection diode element in association with application of a positive voltage, and a second protection diode element in association with application of a negative voltage.

8. The semiconductor device of claim 1, further comprising:
a conductive layer, of a same material and with a same layer thickness as those of a gate electrode of the semiconductor element, formed between the protection diode and the second plug.

9. The semiconductor device of claim 1, wherein
the semiconductor element includes a plurality of semiconductor memories, and
multiple ones of the protection diode is formed along the outer periphery of an array in which the semiconductor memories are disposed collectively.

10. The semiconductor device of claim 1, wherein
the semiconductor element includes a plurality of semiconductor memories, and
the protection diode is electrically connected to a seal ring formed along the outer periphery of an array in which the semiconductor memories are disposed collectively.

11. The semiconductor device of claim 1, wherein
a gate electrode of the semiconductor element is formed of a multilayer film of a metal silicide layer and a polysilicon layer.

12. The semiconductor device of claim 1, wherein
the first interlayer dielectric layer is formed of a multilayer film of a silicon nitride layer and a silicon oxide layer.

13. The semiconductor device of claim 1, wherein
the first plug and the second plug are each made of a metal plug filled with a refractory metal.

14. A semiconductor device, comprising:
a semiconductor element and a protection diode both formed on a semiconductor substrate;
a first interlayer dielectric layer formed over the semiconductor substrate so as to cover the semiconductor element and the protection diode;
a first plug formed in the first interlayer dielectric layer and electrically connected to the semiconductor element;
a second plug formed in the first interlayer dielectric layer and electrically connected to the protection diode;
a first interconnect electrically connected to the first plug, and a second interconnect electrically connected to the second plug, both formed on the first interlayer dielectric layer;
a second interlayer dielectric layer formed over the first interlayer dielectric layer so as to cover the first interconnect and the second interconnect;
a third plug formed in the second interlayer dielectric layer and electrically connected to the first interconnect; and
a fourth plug formed in the second interlayer dielectric layer and electrically connected to the second interconnect, wherein
the area of the top surface of the fourth plug is greater than the area of the top surface of the third plug.

15. The semiconductor device of claim 14, wherein
the area of the top surface of the second plug is greater than the area of the top surface of the first plug.

16. The semiconductor device of claim 14, wherein
the planar shape of the fourth plug is a circle or an elongated circle.

17. The semiconductor device of claim 16, wherein
the elongated circle is an elongated circle with a length ratio of long side to short side of more than or equal to 2.

18. The semiconductor device of claim 14, wherein
the first interconnect is any one of a film made of a material selected from the group consisting of silicon, tungsten, titanium, titanium nitride, aluminum, copper, tantalum, ruthenium, vanadium, or manganese, or a compound thereof, a multilayer film formed of either aluminum or an aluminum compound, titanium, and titanium nitride, and a multilayer film formed of either copper or a copper compound, tantalum, and tantalum nitride.

19. The semiconductor device of claim 14, wherein
the second interlayer dielectric layer is a multilayer film formed of a low-permittivity layer and a metal diffusion barrier layer.

20. The semiconductor device of claim 14, wherein
the second interlayer dielectric layer is either a multilayer film formed of a silicon oxide layer including fluorine, a silicon nitride layer, and a silicon oxide layer, or a multilayer film formed of a silicon oxide layer including carbon, a silicon carbide layer including nitrogen, and a silicon carbide layer including oxygen.

21. A method for fabricating a semiconductor device, comprising acts of
(a) forming a semiconductor element on a semiconductor substrate;
(b) forming a protection diode on the semiconductor substrate;
(c) forming a first interlayer dielectric layer over the semiconductor substrate so as to cover the semiconductor element and the protection diode;
(d) forming a first contact opening reaching the semiconductor element, and a second contact opening reaching the protection diode both in the first interlayer dielectric layer; and
(e) filling the first contact opening and the second contact opening with a conductive material, wherein
in the act (d), the second contact opening reaches the protection diode before the first contact opening reaches the semiconductor element.

22. The method for fabricating a semiconductor device of claim 21, wherein
the protection diode includes a diode element directly coupled to the substrate, and
in the act (a), a gate electrode of the semiconductor element is formed so as to be connected to the diode element directly coupled to the substrate.

23. The method for fabricating a semiconductor device of claim 22, wherein
the acts (a) and (b) are performed substantially concurrently.

24. The method for fabricating a semiconductor device of claim 21, wherein
in the act (b), a first protection diode element in association with application of a positive voltage, and a second protection diode element in association with application of a negative voltage, are formed.

25. The method for fabricating a semiconductor device of claim 21, wherein
in the act (a), substantially concurrently with an act of forming a gate electrode of the semiconductor element, a conductive layer, of a same material and with a same layer thickness as those of the gate electrode is formed over the protection diode.

26. The method for fabricating a semiconductor device of claim 21, wherein
in the act (d), the act of forming the first contact opening and the act of forming the second contact opening are performed separately.

27. The method for fabricating a semiconductor device of claim 21, wherein
in the act (d), the act of forming the first contact opening and the act of forming the second contact opening are performed substantially concurrently.

28. A method for fabricating a semiconductor device, comprising acts of:
(a) forming a semiconductor element on a semiconductor substrate;
(b) forming a protection diode on the semiconductor substrate;
(c) forming a first interlayer dielectric layer over the semiconductor substrate so as to cover the semiconductor element and the protection diode;
(d) forming a first contact opening reaching the semiconductor element, and a second contact opening reaching the protection diode both in the first interlayer dielectric layer;
(e) filling the first contact opening and the second contact opening with a conductive material, and forming a first plug and a second plug, respectively;
(f) forming a first interconnect so as to be electrically connected to the first plug, and forming a second interconnect so as to be electrically connected to the second plug, both on the first interlayer dielectric layer;
(g) forming a second interlayer dielectric layer over the first interlayer dielectric layer so as to cover the first and the second interconnects;
(h) forming a third contact opening reaching the first interconnect and a fourth contact opening reaching the second interconnect both in the second interlayer dielectric layer; and
(i) filling the third contact opening and the fourth contact opening with a conductive material, and forming a third plug and a fourth plug, respectively, wherein
in the act (h), the fourth contact opening reaches the second interconnect before the third contact opening reaches the first interconnect.

29. The method for fabricating a semiconductor device of claim 28, wherein
in the act (d), the second contact opening reaches the protection diode before the first contact opening reaches the semiconductor element.

30. The method for fabricating a semiconductor device of claim 28, wherein
in the act (h), the act of forming the third contact opening and the act of forming the fourth contact opening are performed separately.

31. The method for fabricating a semiconductor device of claim 28, wherein
in the act (h), the act of forming the third contact opening and the act of forming the fourth contact opening are performed substantially concurrently.
